(19) United States
(12) Patent Application Publication
(10) Pub. No.: US 2008/0089038 A1
(43) Pub. Date: Apr. 17, 2008

(54) Battery protection system

(76) Inventors: Nabil Dali, Chatenay Malabry (FR); Abdelaziz Laboudi, Wuppertal (DE)

Correspondence Address: DELPHI TECHNOLOGIES, INC., M/C 480-410-202, PO BOX 5052, TROY, MI, 48007, US

(21) Appl. No.: 11/974,322

(22) Filed: Oct. 12, 2007

(30) Foreign Application Priority Data
Oct. 13, 2006 (GB) 0620266.7
Dec. 12, 2006 (EP) 06301244.7

(51) Int. Cl. H05K 5/00

(52) U.S. Cl. 361/728

(57) ABSTRACT

The battery protection system in accordance with the invention comprises a case; switching means mounted in the case and having a first terminal for electrical connection to a charge source for a battery, and a second terminal for electrical connection to the battery; signal input means attached to the case to receive one or more signals from control means; a control board mounted in the case and connected between the switching means and the signal input means to control the operation of the switching means as a function of the said one or more signals; and a removable coating covering the switching means, the terminals and the control board in the case.

### TECHNICAL FIELD

The present invention relates to a battery protection system, and in particular to a battery protection system for the battery of a motor vehicle.

### BACKGROUND OF THE INVENTION

Generally, known battery protection systems do not lend themselves to easy maintenance and do not allow different assembly configurations. Moreover, known systems tend to occupy considerable space.

In known battery protection systems, a relay is connected to a remote on-board computer which communicates with the relay and performs functions controlling or managing the battery, of diagnosing the relay or the battery, and other functions. It is therefore necessary to design the relay and the on-board computer in parallel to ensure their compatibility. Moreover, modification of one of the functions performed by the on-board computer can require modification of other functions.

### SUMMARY OF THE INVENTION

An aim of the invention is to overcome the disadvantages mentioned above.

To this end, a battery protection system in accordance with the invention comprises a case; switching means mounted in the case and having a first terminal for electrical connection to a source of charge for a battery, and a second terminal for electrical connection to the battery; signal input means attached to the case to receive one or more signals from control means; a control board mounted in the case and connected between the switching means and the signal input means to control the operation of the switching means as a function of the said one or more signals; and a removable coating covering the switching means, the terminals and the control board in the case.

Due to these characteristics, the protection system has several advantages. The control board can be configured to perform functions of battery management or diagnostics, and it is not necessary to take into account the operation of an on-board computer or other controller when these functions are being developed. It is only necessary to ensure compatibility of the signal or signals exchanged at the signal input means. The use of a removable coating, such as a thermofusible adhesive, ensures the seal and means that one or more components in the case can be removed and/or replaced for maintenance or for a change of configuration, without destruction of the whole system. The system in accordance with the present invention lends itself to compact assembly of small volume.

The removable coating is preferably a thermofusible adhesive.

The switching means are preferably a relay. The relay is preferably a bistable relay, which preferably has a default position which electrically connects the first and the second terminal. This arrangement guarantees that the battery remains connected in case of signal failure.

Preferably, the case has an opening adjacent to the switching means. This permits easy evacuation of the heat generated by the switching means. The opening can also extend adjacently to the control board.

In operation, the said switching means advantageously have a hot portion and a cold portion, the said control board being arranged adjacently to the said cold portion, at a distance from the said hot portion. Thus, the control board is not subjected or is not greatly subjected to the heat generated by the hot portion. Therefore it does not have to be designed to resist high temperatures. Preferably, the control board is connected to the switching means by electrical contacts which are situated at the level of the cold portion.

In accordance with a particular embodiment, the said switching means comprise a relay box, the said terminals projecting from the said relay box, the said relay box, the said control board and the said signal input means forming an assembly of substantially rectangular shape. This configuration is particularly effective for the system to be a compact assembly of small volume.

Preferably, the said control board includes board control means able to implement a process for battery management and/or battery diagnostics.

### BRIEF DESCRIPTION OF THE DRAWINGS

The invention will be better understood and other aims, details, characteristics and advantages of it will become more clearly apparent in the course of the following description of several particular embodiments of the invention, given solely by way of illustration and in non-limiting manner, with reference to the attached drawings. In these drawings:

FIG. 1 is a perspective view of a battery protection system in accordance with a first embodiment of the invention, and

FIG. 2 is a perspective view of a battery protection system in accordance with a second embodiment of the invention.

### DESCRIPTION OF THE PREFERRED EMBODIMENT

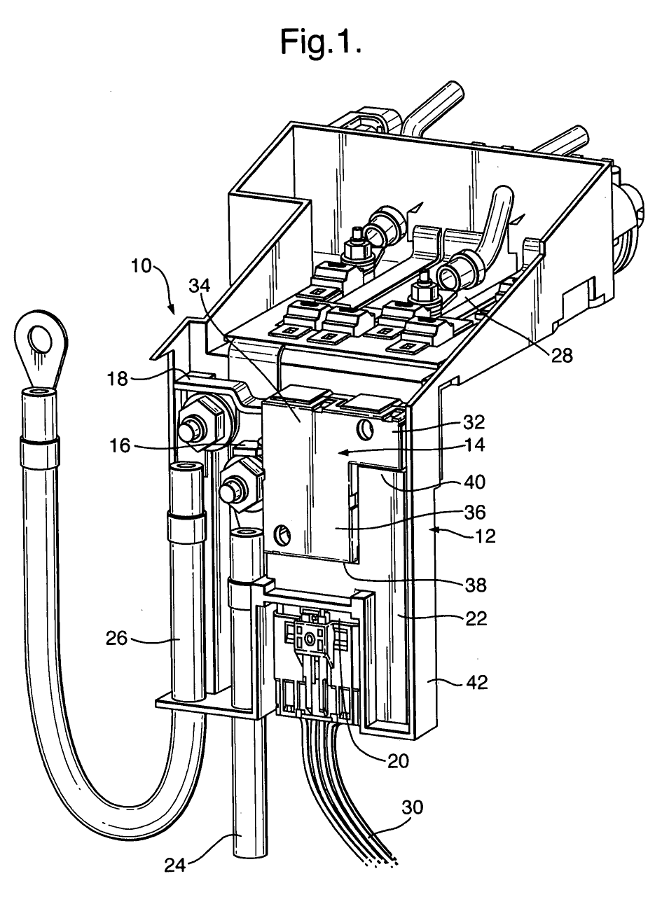

With reference to FIG. 1, the battery protection system 10 comprises a case 12; a relay 14 mounted in the case 12 and having a first terminal 16 and a second terminal 18; an input signal connector 20 attached to the case 12; and a control board 22 mounted in the case 12 and connected between the relay 14 and the input signal connector 20. A removable coating, preferably a thermofusible adhesive, covers the relay 14, the terminals 16 and 18 and the control board 22 in the case 12. The removable coating could only cover certain of these elements; for example, the terminals 16 and 18 could be not covered.

The relay 14, which is preferably a bistable relay, preferably has a default position in which the first and second terminals are electrically connected. The first terminal is electrically connected to an alternator or to another charge source for a battery (not shown) by a first electric wire 24. The second terminal 18 is connected to the battery by a second electric wire 26. The first terminal 16 is also electrically connected to a circuit 28 providing power to one or more electrical loads (not shown).

The relay 14 includes a relay box 32 and the terminals 16 and 18 project from the relay box 32. The internal structure of the relay box 32 presents at least one internal coil and is not described in detail here. In operation, the relay box 32 has a cold zone 36 at the level of the internal coil, and a hot zone 34.

The input signal connector 20 is electrically connected to signal wires 30 which receive signals from (and/or send signals to) control means (not shown). The control means can be an engine control unit for a motor vehicle, and/or one or more sensors. It is not necessary for these control means to be able to perform a function of battery management and/or battery or relay diagnostics.

The control board 22 electrically connects the connector 20 to the relay 14. The control board 22 has components suitable to control the operation of the relay 14 as a function of the signals received by the connector 20, for example a micro-controller forming board control means. With this arrangement, battery management can be performed; it is possible to provide short-circuit protection; and diagnostics are possible for the battery and/or the relay 14. The functions of battery management and/or diagnostics can be designed independently of the control means connected to the control board 22 by the connector 20. The control board 22 is for example made in the form of a printed circuit.

The control board 22 is connected to the relay 14 by electrical contacts 38 which are situated at the level of the cold portion 36 and are not therefore subjected to the heat released by the hot portion 34. The electrical contacts 38 are for example soldered or force-fitted.

Generally, the control board 22 is adjacent to the cold portion 36 and distant from the hot portion 34, except optionally at a portion of small dimension 40. The control board 22 is also arranged at a distance from the terminals 16 and 18, which are also hot in operation.

The case 12 comprises a main part 42 and a cover (not shown). The cover covers the terminals 16 and 18, the ends of the wires 24 and 26 and the circuit 28. However, the cover has an opening at the level of the relay box 32, of the control board 22 and of the connector 20, which permits better evacuation of heat.

As shown in FIG. 1, the relay box 32, the control board 22 and the connector 20 do not all have a rectangular shape, but form an assembly which has a substantially rectangular shape. This permits limitation of space occupied.

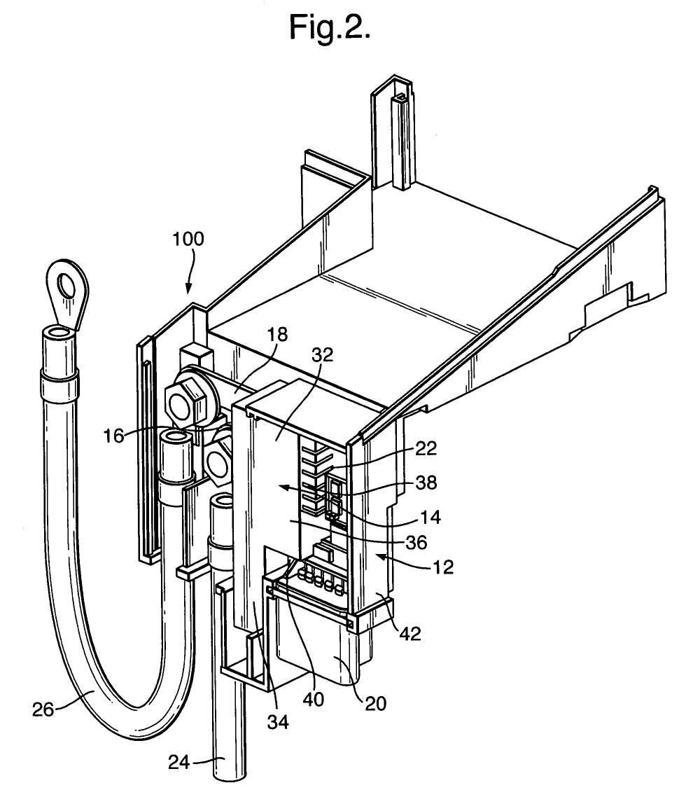

The battery protection system 100 of FIG. 2 is substantially the same as in FIG. 1, with the exception of a modification to the arrangement of the components, and the same parts have been designated by the same reference numbers.

Although the invention has been described in connection with several particular embodiments, it is quite obvious that it is in no way limited to them and that it includes all the technical equivalents of the means described and their combinations if these fall within the scope of the invention.

1. Battery protection system comprising:
a case;
switching means mounted in the case and having a first terminal for electrical connection to a charge source for a battery;
a second terminal for electrical connection to the battery;
signal input means attached to the case to receive one or more signals from a control means;
a control board mounted in the case and connected between the switching means and the signal input means to control the operation of the switching means as a function of the said one or more signals; and
a removable coating covering the switching means, the terminals and the control board in the case.

2. A battery protection system as described in claim 1, wherein the removable coating is a thermofusible adhesive.

3. A battery protection system as described in claim 1, wherein the switching means comprise a relay.

4. A battery protection system as described in claim 3, wherein the relay is a bistable relay having a default position that electrically connects the first terminal and the second terminal.

5. A battery protection system as described in claim 1, wherein the case has an opening adjacent to the switching means.

6. A battery protection system as described in claim 1, wherein, in operation, the switching means comprise a hot portion and a cold portion, said control board being arranged adjacently to the said cold portion, at a distance from said hot portion.

7. A battery protection system as described in claim 6, wherein the control board is connected to the switching means by electrical contacts that are situated at the level of the cold portion.

8. A battery protection system as described in claim 1:
wherein the switching means comprise a relay box; and
wherein the terminals projecting from the relay box, the relay box, the control board, and the said signal input means together form an assembly having a substantially rectangular shape.

9. A battery protection system as described in claim 1, wherein the control board includes board control means able to implement a process for battery management and/or battery diagnostics.
